(19) United States
(12) Patent Application Publication
(10) Pub. No.: US 2015/0160999 A1
(43) Pub. Date: Jun. 11, 2015

(54) SOLID STATE DRIVE CONTROLLER, SOLID STATE DRIVE, DATA PROCESSING METHOD OF SOLID STATE DRIVE, MULTI-CHANNEL SOLID STATE DRIVE, RAID CONTROLLER AND COMPUTER-READABLE RECORDING MEDIUM HAVING RECORDED THEREIN COMPUTER PROGRAM FOR PROVIDING SEQUENCE INFORMATION TO SOLID STATE DRIVE

(71) Applicant: SAMSUNG ELECTRONICS CO., LTD., Suwon-si (KR)

(72) Inventors: Jung-Min Seo, Seongnam-si (KR); Ju-Pyung Lee, Suwon-si (KR)

(21) Appl. No.: 14/413,598

(22) PCT Filed: Jul. 15, 2013
(86) PCT No.: PCT/KR2013/006323

§ 371 Date: Jan. 8, 2015

(30) Foreign Application Priority Data
Jul. 13, 2012 (KR) 10-2012-0076824

(51) Int. Cl. G06F 11/10; G11C 29/52

(52) U.S. Cl. CPC G06F 11/108; G06F 11/1072; G11C 29/52

(57) ABSTRACT

Disclosed are a solid state drive controller, a solid state drive, a data processing method of the solid state drive, a multi-channel solid state drive, a RAID controller, and a computer-readable recording medium which stores a computer program providing sequence information to the solid state drive, which are implemented using a RAID which stores a parity block in a high-endurance memory and a data block in a low-endurance memory.

### TECHNICAL FIELD

The present invention relates to a solid state drive controller, a solid state drive, a data process method of a solid state drive, a multi-channel solid state drive, a redundant array of independent or inexpensive disks (RAID) controller and a computer readable recording medium having recorded therein a computer program for providing sequence information to a solid state drive. More particularly, the present invention relates to a solid state drive controller, a solid state drive, a data process method of a solid state drive, a multi-channel solid state drive, a RAID controller and a computer readable recording medium having recorded therein a computer program for providing sequence information to a solid state drive, which are implemented using a RAID which stores a parity block in a high-endurance memory and a data block in a low-endurance memory.

### BACKGROUND ART

A semiconductor drive or a solid state drive (SSD) refers to a storage device manufactured using a nonvolatile flash memory. In view of characteristics of a flash memory, an in-place overwrite method in which pre-recorded data is deleted and is then rewritten is used to write new data, so that the in-place overwrite method is not used any longer when the number of deletions of the data reached to the maximum number of deletions of the flash memory.

In the SSD, a variety of flash memories, including a single level cell (SLC), a multi-level cell (MLC), a triple level cell (TLC) and combinations thereof, are used.

In consideration of characteristics of the SSD having a NAND cell memory array, in order to achieve in-place updating, a delete operation is necessarily performed before performing a write operation.

The SLC, the MLC and the TLC may be worn out after performing approximately 100,000, 10,000 and 1,000 delete operations, respectively.

In order to extend such a limited lifetime of the SSD, complex processing logic software called a flash translation layer (FTL) performs address mapping, garbage collection and wear-leveling.

Meanwhile, a redundant array of independent or inexpensive disks (RAID) may be constituted by a plurality of solid state disks (SSDs). The RAID architecture enables parallel data accessing or improves fault tolerance by an increased mean time between failure (MTBF).

There are many types of RAIDs. Among others, RAIDs including parity bits may include, for example, RAID 5 and RAID 6.

In the RAID 5 type, data stripes are distributed and stored in multiple disks and a parity bit of XOR operated striped data pieces is also distributed and stored. When a disk failure occurs, the parity bit is used in reconstructing data stored in the failed disk.

The RAID 6 additionally stores a second parity for data, offering improved failure tolerance than RAID 5 type.

In the RAID including the parity bit scheme, data and parities generate different types of access patterns. That is to say, whenever a region of data stored in each disk is updated, a region of a parity corresponding to the data is also updated.

For example, assuming that data is updated just once after the data is written for the first time in the RAID 5 level, a parity block is more frequently updated than a data block by the number of update of data blocks (e.g., a total number of disks−1) on average. In addition, in the RAID 6 level, a parity block is more frequently updated than a data block.

Therefore, in a SSD storage system including a RAID having a parity bit, the lifetime of the SSD may be shortened due to frequent updates of a parity block of the SSD.

### DISCLOSURE

### Technical Problem

The present invention has been made in an effort to solve the problems of the prior art, and the present invention provides a solid state drive controller including a redundant array of independent or inexpensive disks (RAID) which stores a parity block in a high-endurance memory and a data block in a low-endurance memory, thereby improves storage efficiency and lifetime by storing the parity and data blocks transferred from a RAID controller in appropriate types of memories in a RAID group, a solid state drive, a data process method of a solid state drive, a multi-channel solid state drive, a RAID controller and a computer readable recording medium having recorded therein a computer program for providing sequence information to a solid state drive.

### Technical Solutions

In accordance with an aspect of the present invention, the above and other objects can be accomplished by providing a solid state drive controller comprising an interface unit receiving RAID based data including parity blocks and data stripe blocks, and a memory controller controlling the parity blocks to be stored in at least one first memory cell array and the data stripe blocks to be stored in at least one second memory cell array having endurance not higher than that of the first memory cell array.

In accordance with another aspect of the present invention, the above and other objects can be accomplished by providing a solid state drive including an interface unit receiving RAID based data including parity blocks and data stripe blocks, a memory unit including at least one first memory cell array and at least one second memory cell array having endurance not higher than that of the first memory cell array, and a memory controller controlling the memory unit to store the parity blocks in the first memory cell array and the data stripe blocks in the second memory cell array.

In accordance with still another aspect of the present invention, the above and other objects can be accomplished by providing a data processing method of a solid state drive, the data processing method including recognizing sequence information concerning RAID based data including parity blocks and data stripe blocks, based on the sequence information, controlling a memory unit to store a received block with a newly “write” request in a high-endurance memory cell when the received block with a newly “write” request is a parity block and the received block with a newly “write” request in a low-endurance memory cell when the received block with a newly “write” request is not a parity block.

In accordance with yet another aspect of the present invention, the above and other objects can be accomplished by providing a data processing method of a solid state drive, the data processing method including generating sequence information concerning RAID based data including parity blocks and data stripe blocks, based on the sequence information, controlling a memory unit to store a received block with a newly “write” request in a high-endurance memory cell when the received block with a newly “write” request is a parity block and the received block with a newly “write” request in a low-endurance memory cell when the received block requested to newly write is not a parity block.

In accordance with a further aspect of the present invention, the above and other objects can be accomplished by providing a multi-channel solid state drive including an interface unit receiving RAID based data including parity blocks and data stripe blocks, a memory unit including a plurality of memory channels each including at least one first memory cell array and at least one second memory cell array having endurance not higher than that of the first memory cell array, and a memory controller controlling the memory unit to store the parity blocks in the first memory cell array and the data stripe blocks in the second memory cell array.

In accordance with still further aspect of the present invention, the above and other objects can be accomplished by providing a redundant array of independent or inexpensive disks (RAID) controller, the RAID controller providing sequence information to a solid state drive to process RAID based data including parity blocks and data stripe blocks, the solid state drive recognizing sequence information concerning the RAID based data and, based on the sequence information, controlling a memory unit to store a received block with a newly “write” request in a high-endurance memory cell when the received block with a newly “write” request is a parity block and the received block with a newly “write” request in a low-endurance memory cell when the received block with a newly “write” request is not a parity block.

In accordance with another aspect of the present invention, the above and other objects can be accomplished by providing a computer-readable recording medium having recorded therein a computer program for providing sequence information to a solid state drive to process RAID based data including parity blocks and data stripe blocks, the solid state drive recognizing sequence information concerning the RAID based data and, based on the sequence information, controlling a memory unit to store a received block with a newly “write” request in a high-endurance memory cell when the received block with a newly “write” request is a parity block and the received block with a newly “write” request in a low-endurance memory cell when the received block with a newly “write” request is not a parity block.

### Advantageous Effects

As described above, according to the present invention, a hybrid semiconductor storage system and an operating method thereof can be implemented by storing a parity and data blocks transferred from a RAID controller in appropriate types of memories in a RAID group, thereby improving the storage efficiency and lifetime of the storage system.

### DESCRIPTION OF DRAWINGS

In the figures:

FIG. 1 is a block diagram illustrating a connection relationship between an exemplary solid state drive according to an aspect of the present invention and peripheral devices thereof;

FIG. 2 is a detailed block diagram of the exemplary solid state drive shown in FIG. 1;

FIG. 3 is a flowchart illustrating an example of a data processing method of the solid state drive shown in FIG. 2;

FIGS. 4A and 4B are block diagrams illustrating other examples of the solid state drive shown in FIG. 1;

FIGS. 5A to 5C are block diagrams illustrating yet other examples of the solid state drive shown in FIG. 1;

FIG. 6A is a flowchart illustrating an example of a data processing method of the solid state drive shown in FIG. 5A;

FIG. 6B is a flowchart illustrating an example of a data processing method of the solid state drive shown in FIG. 5B;

FIG. 6C is a flowchart illustrating an example of a data processing method of the solid state drive shown in FIG. 5C; and

FIG. 7 is a block diagram illustrating an exemplary multi-channel solid state drive according to another aspect of the present invention.

### MODE FOR INVENTION

Hereinafter, specific embodiments of the present invention will be described in detail with reference to the accompanying drawings.

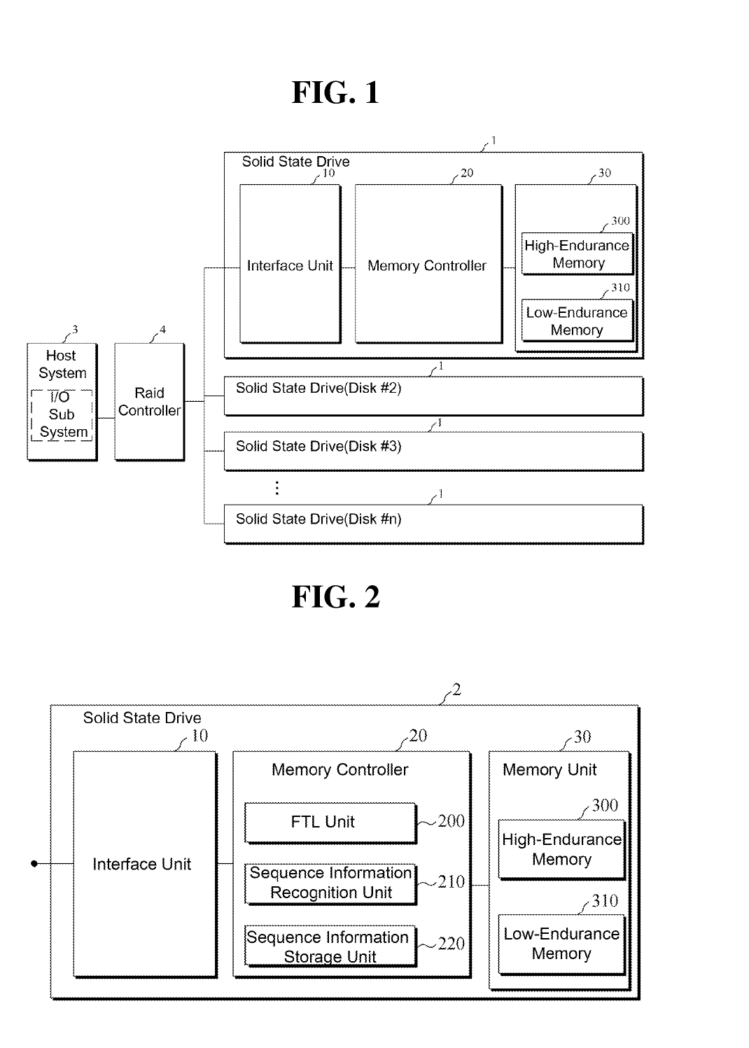

FIG. 1 is a block diagram illustrating a connection relationship between an exemplary solid state drive according to an aspect of the present invention and peripheral devices thereof.

The solid state drives 1 shown in FIG. 1 operate as disks constituting a RAID storage system including distributed parities.

For the sake of convenient explanation, it is assumed that the solid state drives 1 shown in FIG. 1 are disks of a RAID 5 level based left symmetric storage system including four disks. That is to say, “Disk #n” is “Disk #4”.

Each of the solid state drives 1 largely includes an interface unit 10, a memory unit 30 and a memory controller 20.

The interface unit 10 is connected to an I/O sub system of a host system 3 through the RAID controller 4.

The memory unit 30 includes two memory cell arrays having different endurances. That is to say, the memory unit 30 shown in FIG. 1 includes a high-endurance memory 300 and a low-endurance memory 310. In the embodiment illustrated in FIG. 1, the high-endurance memory 300 is a channel including an array of multiple single level cell (SLC) memory cells and the low-endurance memory 310 is a channel including an array of multiple multi level cell (MLC) memory cells.

If RAID based data including parity blocks and data stripe blocks is input to the solid state drive 1 through the interface unit 10, the memory controller 20 controls the memory unit 30 to store the parity blocks in the high-endurance memory 300 and the data stripe blocks in the low-endurance memory 310.

Since the solid state drive 1 operates by four disks constituting the RAID storage system including distributed parities, the data stripe blocks and the parity blocks for ensuring data integrity are received from the host system 3 or the RAID controller 4 according to predetermined rules. In the embodiment illustrated in FIG. 1, four disks (solid state drives 1) of RAID 5 level based storage system are illustrated, the RAID controller 4 or (the I/O sub system of the host system 3) partitions a piece of unit data into three data stripes and one parity to then transmit the same to the solid state drives.

If the solid state drive 1 receives the data stripe blocks and a newly “write” request from the RAID controller 4, the data stripe blocks are stored in the low-endurance memory 310, and if the solid state drive 1 receives the parity block and a newly “write” request from the RAID controller 4, the parity block is stored in the high-endurance memory 300.

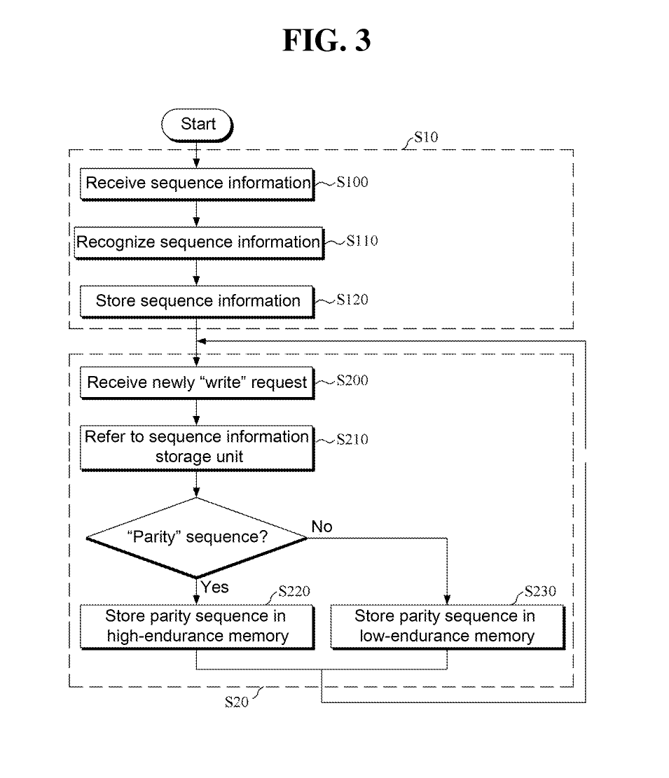

FIG. 2 is a detailed block diagram of the exemplary solid state drive shown in FIG. 1.

The solid state drive 2 shown in FIG. 2 explicitly or inexplicitly receives sequence information of blocks through the interface unit 10.

In the solid state drive 2 shown in FIG. 2, the memory controller 20 further includes a sequence information recognition unit 210, a sequence information storage unit 220 and a flash translation layer (FTL) unit 200.

The sequence information recognition unit 210 recognizes the sequence information indicating sequences of parity blocks and data stripe blocks from the I/O sub system of the host system 3 or the RAID controller 4 through the interface unit 10.

Here, the sequence information may be explicitly provided or inexplicitly provided.

In an example of explicitly providing the sequence information, an indicator indicating whether a received block is a data stripe block or a parity block for each block received through the interface unit 10 may further be provided to the solid state drive 1 as the sequence information.

Table 1 shows an example of explicitly providing sequence information. In Table 1, “D” denotes a data stripe block and “P” denotes a parity block.

TABLE 1

| | Disk #1 | Disk #2 | Disk #3 | Disk #4 |
|---|---|---|---|---|
| Sequence | DDDP | DDPD | DPDD | PDDD |
| information | | | | |

Referring to Table 1, after three consecutive data stripe blocks are received to a disk (Disk #1), a parity block is received.

In an example of inexplicitly providing the sequence information, sequence information, rules for receiving blocks through the interface unit 10 may further be provided as the sequence information to the solid state drive 1.

Table 2 shows an example of inexplicitly providing sequence information. In Table 2, “D” denotes a data stripe block and “P” denotes a parity block.

TABLE 2

| | Disk #1 | Disk #2 | Disk #3 | Disk #4 |
|---|---|---|---|---|
| Sequence | (0, 4, 5 L) | (1, 4, 5 L) | (2, 4, 5 L) | (3, 4, 5 L) |
| information | | | | |

The rules illustrated in Table 2, that is, the sequence information, include three parameters. The first parameter indicates in what place the first parity block is located, the second parameter indicates a cycle in which the next parity block is received, and the third parameter indicates a RAID characteristic.

Referring to Table 2, the first block received in the disk (Disk #1) is a parity block, a block appearing for every four blocks is a parity block (that is, the remaining blocks are data stripe blocks), and the RAID characteristic is left symmetric RAID 5 level.

The sequence information storage unit 220 stores the sequence information explicitly or inexplicitly recognized by the sequence information recognition unit 210.

When the FTL unit 200 receives a newly “write” request for the received block based on the sequence information stored in the sequence information storage unit 220, the received block being a parity block is stored in the high-endurance memory 300 and the received block being a data stripe block is stored in the low-endurance memory 310.

Here, the FTL unit 200 further performs logic block address mapping and wear-leveling on the received block.

Meanwhile, when the sequence information is supplied from the I/O sub system of the host system 3, a general-purpose RAID controller can be advantageously used without a change in the configuration.

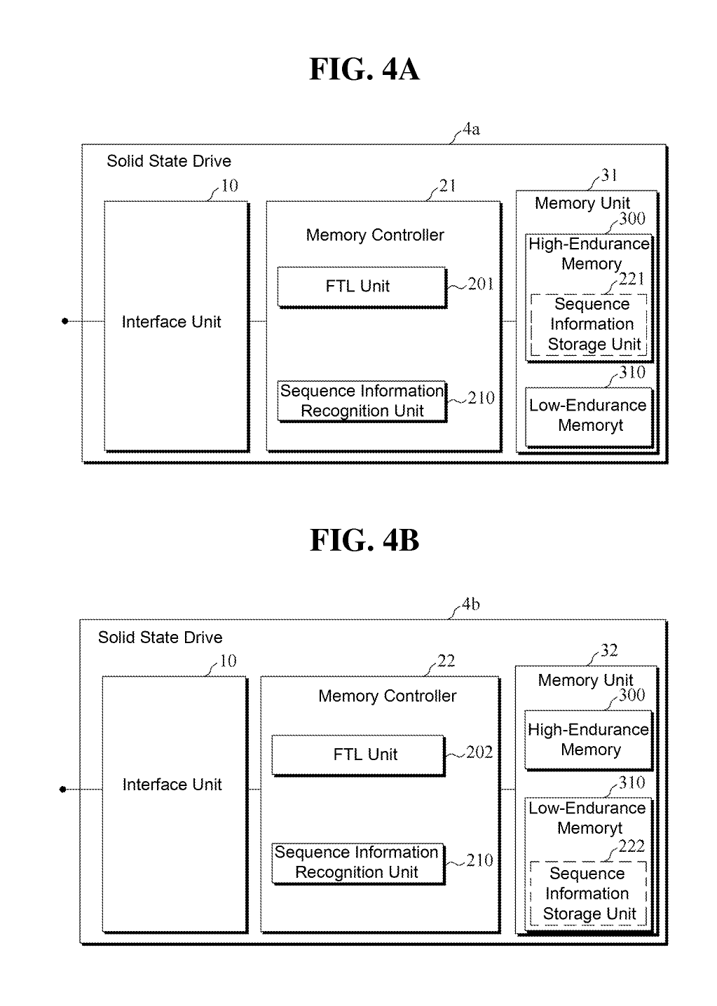

FIG. 3 is a flowchart illustrating an example of a data processing method of the solid state drive shown in FIG. 2.

As illustrated in FIG. 3, the data processing method of the solid state drive includes storing sequence information (S10) and processing data (S20).

In the storing of the sequence information (S10), the sequence information concerning blocks to be processed is recognized and stored.

First, the interface unit 10 receives the sequence information from the I/O sub system of the host system 3 or the RAID controller 4 (S100). As described above with reference to FIG. 2, the sequence information explicitly provided or inexplicitly provided.

Next, the sequence information recognition unit 210 recognizes the explicitly or inexplicitly provided sequence information (S110). The sequence information recognized by the sequence information recognition unit 210 is stored in the sequence information storage unit 220 (S120).

In the processing of the data (S20), the received block is processed based on the sequence information.

First, a newly “write” request for the received block is received through the interface unit 10 (S200).

Then, the FTL unit 200 refers to the sequence information stored in the sequence information storage unit 220 to determine a characteristic of the received block (S210).

If the received block with the newly “write” request is a parity block, the FTL unit 200 stores the parity block in the high-endurance memory (S220). If the received block with the newly “write” request is not a parity block (that is, if the received block with the newly “write” request is a data stripe block), the FTL unit 200 stores the data stripe block in the low-endurance memory (S230).

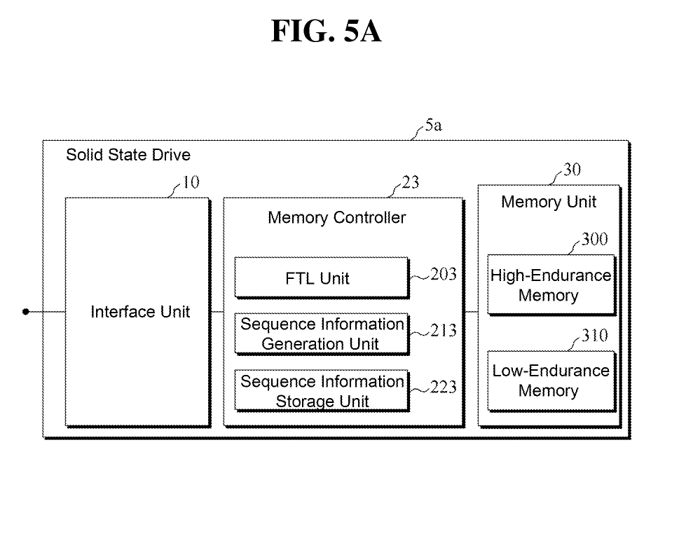

FIGS. 4A and 4B are block diagrams illustrating other examples of the solid state drive shown in FIG. 1.

In the solid state drive 1 shown in FIG. 2, the sequence information storage unit 220 exists within the memory controller 20. However, according to embodiments, the sequence information may be stored in the memory unit 30.

In the solid state drive 4a exemplified in FIG. 4A, a sequence information storage unit 221 is included in a region of the high-endurance memory 300.

In the solid state drive 4b exemplified in FIG. 4B, a sequence information storage unit 222 is included in a region of the low-endurance memory 310.

The solid state drive 4a exemplified in FIG. 4A and the solid state drive 4b exemplified in FIG. 4B operate in substantially the same manner with the solid state drive 2 shown in FIG. 2, except for the position of the sequence information storage unit. A FTL unit 201 shown in FIG. 4A and a FTL unit 202 shown in FIG. 4B may perform substantially the same functions with the FTL unit 200 shown in FIG. 2, except that sequence information is referred to by the high-endurance memory and the low-endurance memory, respectively. In addition, in the solid state drives shown in FIGS. 2, 4A and 4B, the components denoted by the same reference numerals perform the same functions.

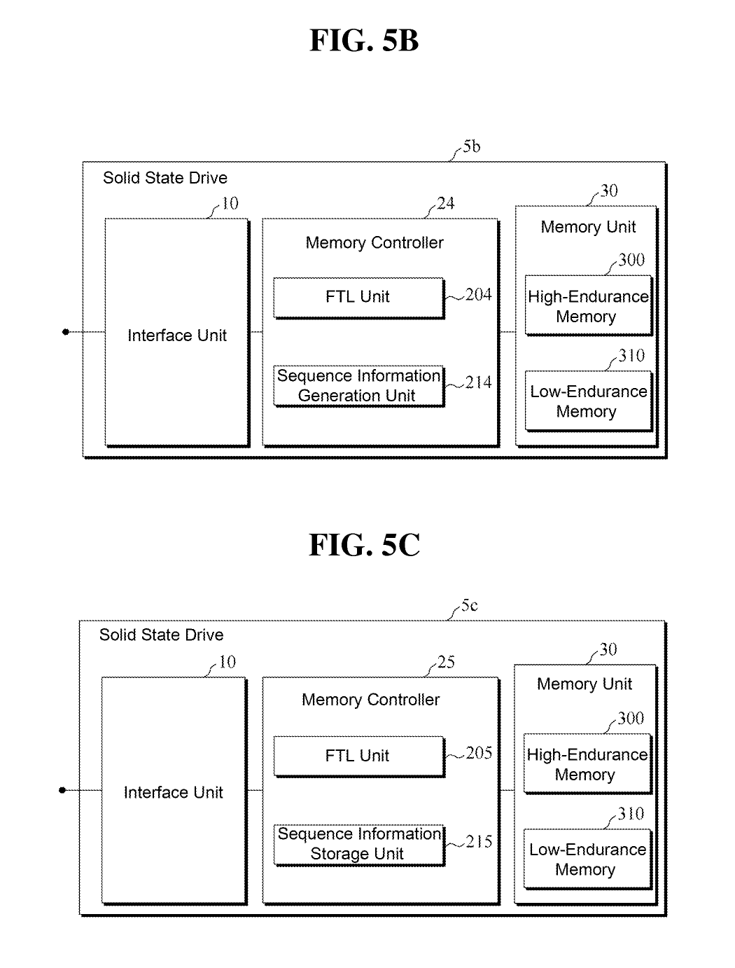

FIGS. 5A to 5C are block diagrams illustrating yet other examples of the solid state drive shown in FIG. 1.

The solid state drive 2 shown in FIG. 2 processes data based on the sequence information explicitly or inexplicitly provided from the I/O sub system of the host system 3 or the RAID controller 4. In the solid state drive 5a shown in FIG. 5A and the solid state drive 5b shown in FIG. 5B, sequence information is directly generated by sequence information generation units 213 and 214 of memory controllers 23 and 24, rather than being provided from an external device.

The sequence information generation units 213 and 214 may generate the sequence information based on access patterns attempted by a RAID controller for a predetermined period of time.

For example, when read, write and erase operations of disks in the RAID are performed based on a RAID level including a distributed parity, e.g., a RAID level 5, a parity block is markedly frequently updated, compared to data stripe blocks. Therefore, when patterns in which some blocks are frequently updated are recognized, the sequence information generation units 213 and 214 may generate sequence information concerning rules in which parity blocks are stored in the frequently updated blocks based on the recognized patterns.

In the embodiment illustrated in FIG. 5A, the sequence information generation unit 213 allows the generated sequence information to be stored in the sequence information storage unit 223 and to be referred to by a FTL unit 203.

In the embodiment illustrated in FIG. 5B, the sequence information generation unit 214 may allow the generated sequence information to be referred to by a FTL unit 204 in real time. In this case, a sequence information storage unit may not be provided.

As illustrated in FIG. 5C, the solid state drive 5c may pre-store sequence information suitable to a characteristic of a current RAID in a sequence information storage unit 215. In this case, a sequence information generation unit may not be provided.

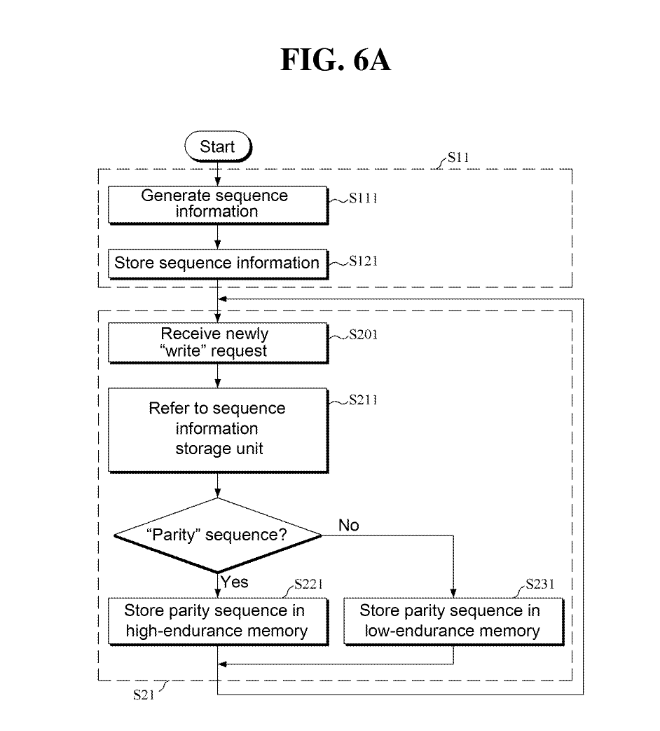

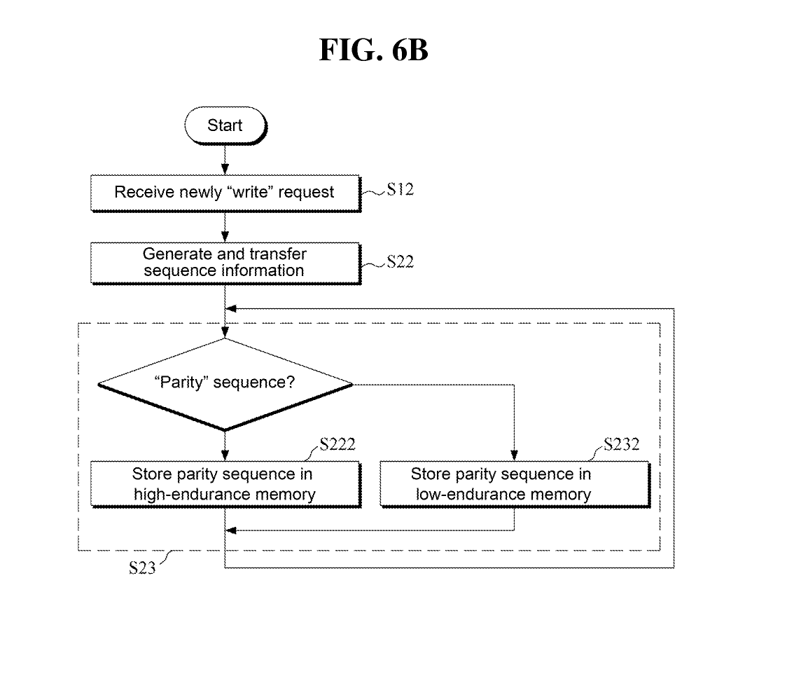

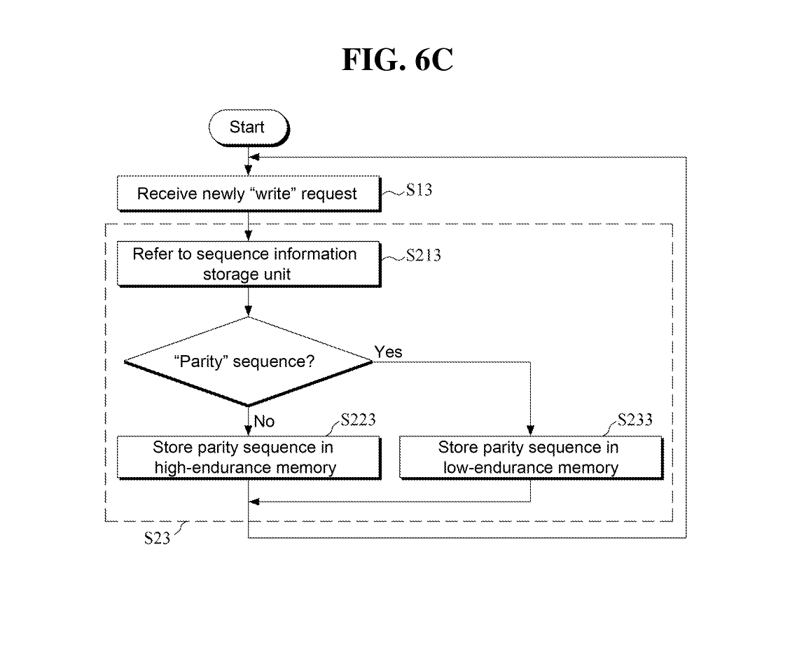

FIGS. 6A to 6C are flowcharts illustrating examples of data processing methods of the solid state drives shown in FIGS. 5A to 5C, respectively.

FIG. 6A is a flowchart illustrating an example of a data processing method of the solid state drive shown in FIG. 5A.

As illustrated in FIG. 6A, the data processing method of the solid state drive shown in FIG. 5A includes generating sequence information (S11) and processing data (S21).

In the generating of the sequence information (S11), the sequence information concerning blocks to be processed is generated and stored.

As described above, the sequence information generation unit generates the sequence information based on access patterns attempted by a RAID controller for a predetermined period of time (S111).

The sequence information recognized by the sequence information recognition unit is stored in the sequence information storage unit (S121).

Next, in the processing of the data (S21), the received block is processed based on the sequence information generated by the sequence information generation unit.

First, a newly “write” request for the received block is received through the interface unit (S201).

Then, the FTL unit refers to the sequence information stored in the sequence information storage unit to determine a characteristic of the received block (S211).

If the received block with a newly “write” request is a parity block, the FTL unit stores the parity block in a high-endurance memory (S221). If the received block with a newly “write” request is not a parity block (that is, if the received block with a newly “write” request is a data stripe block), the FTL unit stores the data stripe block in a low-endurance memory (S231).

FIG. 6B is a flowchart illustrating an example of a data processing method of the solid state drive shown in FIG. 5B.

As illustrated in FIG. 6B, the data processing method of the solid state drive shown in FIG. 5B includes receiving a newly “write” request (S12), generating sequence information (S22), and processing data (S23).

First, if a newly “write” request for the received block is received through the interface unit, the FTL unit requests for generation of sequence information for blocks to be currently processed to the sequence information generation unit (S12).

In the generating of the sequence information (S22), the sequence information generation unit generates the sequence information for blocks to be currently processed based on the access patterns attempted by the RAID controller for a predetermined period of time.

Next, in the processing of the data (S23), a characteristic of a block to be currently processed by the FTL unit is determined based on the sequence information generated by the sequence information generation unit.

If the received block with a newly “write” request is a parity block, the FTL unit stores the parity block in the high-endurance memory (S222). If the received block with the newly “write” request is not a parity block (that is, if the received block with the newly “write” request is a data stripe block), the FTL unit stores the data stripe block in the low-endurance memory (S232).

As illustrated in FIG. 6C, the data processing method of the solid state drive shown in FIG. 5C includes receiving a newly “write” request (S13) and processing data (S23).

First, if a newly “write” request for the received block is received through the interface unit, the FTL unit determines a characteristic of a block to be currently processed based on the sequence information stored in the sequence information storage unit (S213).

If the received block with a newly “write” request is a parity block, the FTL unit stores the parity block in the high-endurance memory (S223). If the received block with the newly “write” request is not a parity block (that is, if the received block with the newly “write” request is a data stripe block), the FTL unit stores the data stripe block in the low-endurance memory (S233).

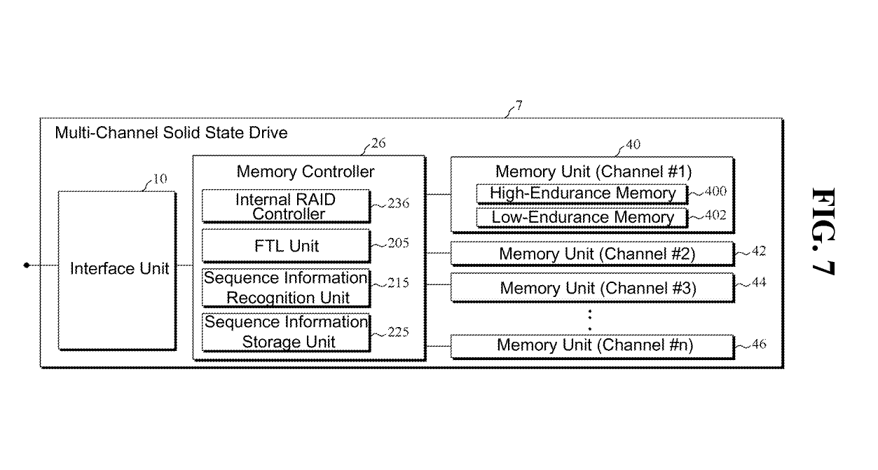

FIG. 7 is a block diagram illustrating an exemplary multi-channel solid state drive according to another aspect of the present invention.

The multi-channel solid state drive 7 shown in FIG. 7 is most featured in that an internal RAID controller capable of storing data in memory units of multiple channels and managing the data based on the RAID algorithm having an intrinsic distributed parity.

The multi-channel solid state drive 7 shown in FIG. 7 includes an interface unit 10, a memory controller 26 and multi-channel memory units 40, 42, 44 and 46, and each channel of the memory units 40, 42, 44 and 46 includes a high-endurance memory 400 and a low-endurance memory 402.

The multi-channel solid state drive 7 shown in FIG. 7 explicitly or inexplicitly receives sequence information of blocks through the interface unit 10.

In the multi-channel solid state drive 7 shown in FIG. 7, the memory controller 26 further includes a sequence information recognition unit 215, a sequence information storage unit 225, an internal RAID controller 236 and a flash translation layer (FTL) unit 205.

The sequence information recognition unit 215 recognizes external sequence information indicating sequences of parity blocks and data stripe blocks from an I/O sub system of a host system or an external RAID controller through the interface unit 10.

Here, the external sequence information may be explicitly or inexplicitly provided.

The sequence information storage unit 225 stores the external sequence information explicitly or inexplicitly recognized by the sequence information recognition unit 215.

The internal RAID controller 236 provides internal sequence information concerning channels in which data stripe blocks to be processed and a parity block are stored, based on the RAID level algorithm employed by the multi-channel solid state drive 7 to the FTL unit 205. The internal sequence information may also be stored in the sequence information storage unit 225 together with the external sequence information.

When a newly “write” request for received blocks is received for a pertinent memory channel and the received blocks are parity blocks, the FTL unit 205 stores the parity blocks in a high-endurance memory (e.g., 400) of the memory channel, and when the received block is a data stripe block, the data stripe block is stored in a low-endurance memory (e.g., 402) of the memory channel, based on the external sequence information and the internal sequence information stored in the sequence information storage unit 225.

Here, the FTL unit 205 further performs logic block address mapping and wear-leveling on the received block.

Throughout the embodiments, the devices and methods for storing frequently updated parity blocks in the high-endurance memory and infrequently updated data stripe blocks in the low-endurance memory have been described.

Here, sizes of storage areas of memory units can be adjusted in consideration of endurance and I/O patterns of the high- and low-endurance memory cells.

For example, when a storage region of a high-endurance memory cell is larger than that of a parity block required by the RAID level (e.g., RAID 5 level), a storage region of the high-endurance memory cell for storing the parity block may remain while a storage region of the low-endurance memory cell for storing the data stripe block is insufficient.

Here, in order to efficiently utilize a space for storing data stripe blocks, some data stored in the low-endurance memory may be shifted to the high-endurance memory to then be stored.

Conversely, when a storage region of a low-endurance memory cell is larger than that of a parity block required by the RAID level (e.g., RAID 5 level), a storage region of the low-endurance memory cell for storing the parity block may remain while a storage region of the high-endurance memory cell for storing the data stripe block is insufficient.

Here, in order to efficiently utilize a space for storing data stripe blocks, some parity blocks stored in the low-endurance memory may be shifted to the high-endurance memory to then be stored.

In addition, when some memory cells are worn out, frequent failures occur to the memory cells after the prolonged use or when rebuilding data, the same sequence information may be recognized and store and the data and parity blocks may be distributed and stored in storage areas of different memories based on the sequence information.

Meanwhile, not only the NAND flash memory cells but also other types of nonvolatile memory cells or volatile memory cells may also be used as the high-endurance memory and the low-endurance memory constituting the memory unit without departing from the scope of the present invention.

Meanwhile, the embodiments of the present invention can be implemented as computer readable codes in computer readable recording media. The computer readable recording media include all kinds of recording apparatuses in which data that can be read by a computer system is stored.

Examples of the computer readable recording media may include ROM, RAM, CD-ROM, magnetic tape, floppy disk, and optical data storage, and transmissions via the Internet (e.g., carrier wave). In addition, the computer readable recording media can be distributed in a computer system connected to a network, and can be stored and operated in forms of computer readable codes. Functional programs, codes, and code segments for implementing the recording/reproducing method can be easily construed by programmers skilled in the art.

Further, the aforementioned embodiments of the present invention are to be considered illustrative, and not restrictive, and the appended claims are intended to cover all such modifications, enhancements, and other embodiments, which fall within the true spirit and scope of the present invention.

1. A solid state drive controller comprising:
an interface unit receiving RAID based data including parity blocks and data stripe blocks; and
a memory controller controlling the parity blocks to be stored in at least one first memory cell array and the data stripe blocks to be stored in at least one second memory cell array having endurance not higher than that of the first memory cell array.

2. The solid state drive controller of claim 1, wherein the memory controller comprises:
a sequence information recognition unit recognizing sequence information indicating sequences of the parity blocks and the data stripe blocks; and
a flash translation layer (FTL) unit storing at least one parity block with a newly “write” request in the first memory cell array and the data stripe blocks with a newly “write” request in the second memory cell array, based on the sequence information.

3. The solid state drive controller of claim 1, wherein the memory controller further comprises a sequence information storage unit storing the sequence information.

4. The solid state drive controller of claim 2, wherein the sequence information recognition unit recognizes the information received from an I/O sub system of a host system or a RAID controller through the interface unit as the sequence information.

5. The solid state drive controller of claim 2, wherein the sequence information recognition unit analyzes the information received from an I/O sub system of a host system or a RAID controller through the interface unit and recognizes the analyzed information as the sequence information.

6. The solid state drive controller of claim 2, wherein the sequence information recognition unit recognizes the sequence information based on access patterns for a predetermined period of time.

7. The solid state drive controller of claim 6, wherein when the access patterns are patterns for frequently updating partial blocks, the sequence information recognition unit recognizes the sequence information to store parity blocks in the partial blocks.

8. The solid state drive controller of claim 1, wherein the first memory cell array is a high-endurance flash memory and the second memory cell array is a low-endurance flash memory.

9. The solid state drive controller of claim 8, wherein the high-endurance flash memory is a single level cell (SLC) and the second memory cell array is a multi-level cell (MLC).

10. The solid state drive controller of claim 8, wherein the high-endurance flash memory is a multi-level cell (MLC) and the second memory cell array is a triple level cell (TLC).

11. The solid state drive controller of claim 1, wherein the RAID based data is RAID level 5 based data.

12. The solid state drive controller of claim 1, wherein the RAID based data is RAID level 6 based data.

13. A solid state drive comprising:
an interface unit receiving RAID based data including parity blocks and data stripe blocks;
a memory unit including at least one first memory cell array and at least one second memory cell array having endurance not higher than that of the first memory cell array; and
a memory controller controlling the memory unit to store the parity blocks in the first memory cell array and the data stripe blocks in the second memory cell array.

14. The solid state drive of claim 13, wherein the memory controller comprises:
a sequence information recognition unit recognizing sequence information indicating sequences of the parity blocks and the data stripe blocks; and
a flash translation layer (FTL) unit storing at least one parity block with a newly “write” request in the first memory cell array and the data stripe blocks with a newly “write” request in the second memory cell array, based on the sequence information.

15. The solid state drive of claim 13, wherein the memory controller further comprises a sequence information storage unit storing the sequence information.

16. The solid state drive of claim 14, wherein the sequence information recognition unit recognizes the information received from an I/O sub system of a host system or a RAID controller through the interface unit as the sequence information.

17. The solid state drive of claim 14, wherein the sequence information recognition unit analyzes the information received from an I/O sub system of a host system or a RAID controller through the interface unit and recognizes the analyzed information as the sequence information.

18. The solid state drive of claim 14, wherein the sequence information recognition unit recognizes the sequence information based on access patterns for a predetermined period of time.

19. The solid state drive of claim 18, wherein when the access patterns are patterns for frequently updating partial blocks, the sequence information recognition unit recognizes the sequence information to store parity blocks in the partial blocks.

20. The solid state drive of claim 13, wherein the first memory cell array is a high-endurance flash memory and the second memory cell array is a low-endurance flash memory.

21.-36. (canceled)
